(19) United States
(12) Patent Application Publication
(10) Pub. No.: US 2017/0271840 A1
(43) Pub. Date: Sep. 21, 2017

(54) METHOD FOR FABRICATING SURFACE EMITTING LASER

(71) Applicant: SUMITOMO ELECTRIC INDUSTRIES, LTD., Osaka (JP)

(72) Inventor: Yukihiro TSUJI, Yokohama-shi (JP)

(73) Assignee: SUMITOMO ELECTRIC INDUSTRIES, LTD., Osaka (JP)

(21) Appl. No.: 15/459,766

(22) Filed: Mar. 15, 2017

(30) Foreign Application Priority Data
Mar. 16, 2016 (JP) 2016-052434

(51) Int. Cl. H01S 5/02; H01S 5/187; H01S 5/343; H01S 5/026

(52) U.S. Cl. CPC H01S 5/0205; H01S 5/026; H01S 5/187; H01S 5/0203; H01S 5/3432

(57) ABSTRACT

A method for fabricating a surface emitting laser includes the steps of: preparing an epitaxial substrate including a substrate and a laminate disposed on the substrate, the laminate including a Bragg reflector and an active layer; forming a mask for defining a semiconductor post on the epitaxial substrate; after forming the mask, placing the epitaxial substrate in an etching apparatus with an end point detector including an optical device; carrying out plasma etching of the epitaxial substrate by supplying a gas including boron chloride and chlorine in the etching apparatus; and stopping the plasma etching in response to an end point detection from the end point detector of the etching apparatus. The optical device of the end point detector detects an end point of a process through a viewport of the etching apparatus. The plasma etching is carried out in a process pressure of one Pascal or less.

### BACKGROUND OF THE INVENTION

Field of the Invention

The present invention relates to a method for fabricating a surface emitting laser. This application claims the benefit of priority from Japanese Patent Application No. 2016-052434 filed on Mar. 16, 2016, which is herein incorporated by reference in its entirety.

Related Background Art

Patent Document 1 (Japanese Patent No. 5034662, or Japanese Unexamined Patent Application Publication No. 2008-028370) discloses a surface emitting laser and a method for fabricating the surface emitting laser.

### SUMMARY OP INVENTION

A surface emitting laser includes a semiconductor post in which a laser cavity is included. The semiconductor post includes an upper distributed Bragg reflector, an active layer and a lower distributed Bragg reflector. In the fabrication of the surface emitting laser, a laminate including semiconductor layers for forming the upper distributed Bragg reflector, the active layer and the lower distributed Bragg reflector is etched by using, for example, boron trichloride to form the semiconductor post of the surface emitting laser.

In the step of etching the laminate, an end point detector is used for accurately monitoring etching. Specifically, in the dry etching process such as a plasma etching process, the end point detector receives light (light from the plasma) through the view port of the etching chamber for monitoring etching. In the dry etching process using boron trichloride as an etchant, the intensity of light transmitted through the viewport in a time zone close to the end point of the etching becomes weaker than the intensity of light transmitted through the viewport in a time zone close to the start of etching. It is experimentally found that the change in optical intensity transmitted through the viewport is caused by increase in material deposited on the viewport. Specifically, etching in this method continuously produces boron compound from boron trichloride, and the boron product continues to deposit on the inner wall of the chamber and the viewport of the etching apparatus during the etching. The boron product, which is deposited on the viewport during the etching, shields a part of light from the object to be observed in the etching apparatus. The deposition of the boron product makes the end point detection undetectable. It is considered to form the semiconductor post in a short time by enhancing the plasma density in the etching apparatus before the signal is undetectable due to the deposition of the boron product on the viewport. The deterioration in the intensity of the transmitted light, however, lowers the accuracy of the end point detection regardless of the length of the etching time. The variation in the deposition amount of the boron product per etching run also lowers the accuracy of the end point detection. In either case, the boron deposit prevents stable fabrication of surface emitting lasers.

A method for fabricating a surface emitting laser according to an aspect of the present invention includes the steps of: preparing an epitaxial substrate including a substrate and a laminate disposed on the substrate, the laminate including a first Bragg reflector, an active layer, and a second Bragg reflector; forming a mask for defining a semiconductor post on the epitaxial substrate; after forming the mask, placing the epitaxial substrate in a chamber of an etching apparatus with an end point detector including an optical device; carrying out plasma etching of the epitaxial substrate with the mask by supplying a gas including boron chloride and chlorine in the chamber of the etching apparatus; and stopping the plasma etching in response to an end point detection from the end point detector of the etching apparatus. The optical device of the end point detector detects an end point of a process through a viewport of the etching apparatus. In addition, the plasma etching is carried out in a process pressure of one Pascal or less.

The above-described objects and the other objects, features, and advantages of the present invention become more apparent from the following detailed description of the preferred embodiments of the present invention proceeding with reference to the attached drawings.

### BRIEF DESCRIPTION OF THE DRAWINGS

FIG. 1 is a schematic view showing a major step in a method for fabricating a surface emitting laser according to the present embodiment.

FIG. 2 is a schematic view showing a major step in the method for fabricating the surface emitting laser according to the present embodiment.

FIG. 3 is a schematic view showing an exemplary etching apparatus according to the present embodiment.

FIG. 4 is a schematic view showing a major step in the method for fabricating the surface emitting laser according to the present embodiment.

FIGS. 5A, 5B, and 5C are schematic diagrams each showing etching in Examples.

FIG. 6 is a schematic view showing a major step in the method for fabricating the surface emitting laser according to the present embodiment.

FIG. 7 is a schematic view showing a major step in the method for fabricating the surface emitting laser according to the present embodiment.

FIG. 8 is a schematic view showing a major step in the method for fabricating the surface emitting laser according to the present embodiment.

FIG. 9 is a schematic view showing a major step in the method for fabricating the surface emitting laser according to the present embodiment.

FIG. 10 is a schematic view showing a major step in the method for fabricating the surface emitting laser according to the present embodiment.

### DESCRIPTION OF THE EMBODIMENTS

Specific embodiments according to the present above aspects are described below.

A method for fabricating a surface emitting laser according to an embodiment includes the steps of: (a) preparing an epitaxial substrate including a substrate and a laminate disposed on the substrate, the laminate including a first Bragg reflector, an active layer, and a second Bragg reflector; (b) forming a mask for defining a semiconductor post on the epitaxial substrate; (c) after forming the mask, placing the epitaxial substrate in a chamber of an etching apparatus with an end point detector including an optical device; (d) carrying out plasma etching of the epitaxial substrate with the mask by supplying a gas including boron chloride and chlorine in the chamber of the etching apparatus; and (e) stopping the plasma etching in response to an end point detection from the end point detector of the etching apparatus. The optical device of the end point detector detects an end point of a process through a viewport of the etching apparatus. In addition, the plasma etching is carried out in a process pressure of one Pascal or less.

In the method for fabricating the surface emitting laser, the etching apparatus generates plasma of boron chloride and chlorine. Chlorine particles in the plasma in the etching apparatus are consumed to produce the chloride of a constituent element(s) of semiconductor in the laminate of the surface emitting laser. The semiconductor layer in the laminate is etched as a result of producing the chloride. A part of boron particles in the plasma may adhere to the chamber inner wall and the viewport of the etching apparatus. A process pressure of less than one Pascal in the etching may provide a gas phase in the chamber of the etching apparatus with a mean free path which allows chlorine particles in the plasma to reach the viewport of the chamber. Chlorine particles in the plasma may produce chlorides from the boron deposited on the viewport and are also consumed to reduce the boron deposition. Carrying out the etching in the above process pressure enables the cleaning of the viewport in addition to the etching the semiconductor.

In the method for fabricating a surface emitting laser according to an embodiment, the end point detector may have an optical interference type detector, and the optical device may include an optical source and a spectrometer.

In the method for fabricating the surface emitting laser, the intensity of the interference light is used to estimate the film thickness of the remaining part of the semiconductor laminate for forming the distributed Bragg reflector, allowing the detection of the end point in the etching.

In the method for fabricating a surface emitting laser according to an embodiment, preferably, the first Bragg reflector in the laminate includes a GaAs/AlGaAs superlattice, and the substrate has a GaAs surface.

In the method for fabricating the surface emitting laser, the end point detector receives reflected components, which come from both the GaAs surface of the substrate and the GaAs/AlGaAs multilayer film in the laminate to be etched, through the viewport to detect the end point using the reflected components.

In the method for fabricating a surface emitting laser according to an embodiment, preferably, the etching apparatus includes a stage having a lower electrode, an inductive-coupling coil disposed outside the chamber thereof; a first radio frequency power supply coupled to the lower electrode, and a second radio frequency power supply coupled to the inductive-coupling coil. The epitaxial substrate is placed on the stage during the plasma etching. In addition, the second radio frequency power supply has a capability of supplying a power of 50 watts or more.

In the method for fabricating the surface emitting laser, the supply power (ICP power) of 50 watts or more allows the second radio frequency power supply to apply a large power to the inductive-coupling coil, so that ions in the plasma can reach the viewport by overcoming the bias power that the first radio frequency power supply applies to the lower electrode.

Teachings of the present invention can be readily understood by considering the following detailed description with reference to the accompanying drawings shown as examples. Referring to the accompanying drawings, embodiments of a method for fabricating a surface emitting laser according to the present invention will be described. To facilitate understanding, identical reference numerals are used, where possible, to designate identical elements that are common to the figures.

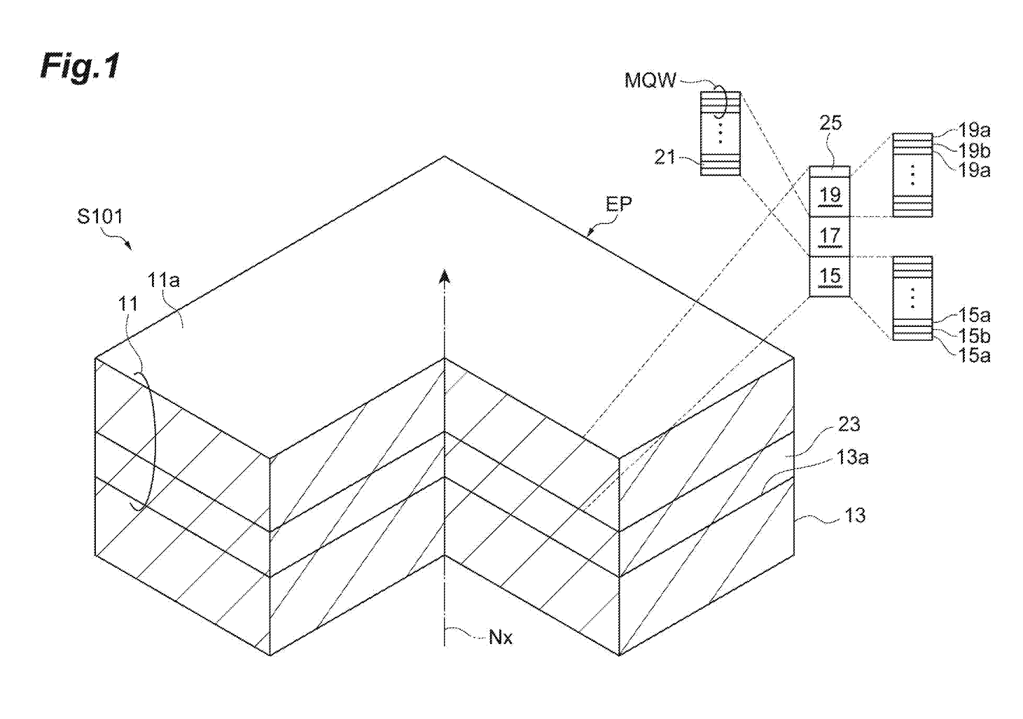

With reference to FIGS. 1 to 8, embodiments of a method for fabricating a surface emitting laser will be described. FIGS. 1, 2, 4, 6 to 8 each show a single device section for the surface emitting laser to be fabricated. The following embodiments describe the fabrication of, for example, a vertical cavity surface emitting laser (VCSEL).

In step S101, as shown in FIG. 1, an epitaxial substrate EP for fabricating a surface emitting laser is prepared. The epitaxial substrate EP includes a laminate 11 and a substrate 13, and the laminate 11 is disposed on a principal surface 13a of the substrate 13. The laminate 11 has a principal surface 11a. The laminate 11 includes a first stacked semiconductor layer 15 constituting a first distributed Bragg reflector, a semiconductor region 17 constituting an active layer, and a second stacked semiconductor layer 19 constituting a second distributed Bragg reflector. The first stacked semiconductor layer 15, the semiconductor region 17 and the second stacked semiconductor layer 19 are arranged in the direction of an axis Nx normal to the principal surface 13a of the substrate 13. The semiconductor region 17 may include a quantum well structure MQW serving as the active layer for light emission, and may further include, for example, an Al-based III-V semiconductor layer 21 for a current confinement structure. If necessary, the laminate 11 of the epitaxial substrate EP may include a buffer layer 23 and/or an upper contact layer 25. Specifically, the semiconductor layer for forming the buffer layer 23 is disposed between the first stacked semiconductor layer 15 and the substrate 13, and the semiconductor layer for forming the upper contact layer 25 is disposed on the second stacked semiconductor layer 19. In the present embodiment, in order to prepare the epitaxial substrate EP, the epitaxial substrate EP is formed in the following process. The substrate 13 is prepared for growing semiconductor layers thereon by using an epitaxial growth method. The substrate 13 may include a semiconductor wafer, specifically, a GaAs wafer. The laminate 11 is grown on the principal surface 13a of the substrate 13 by using, for example, a molecular beam epitaxy method and/or a metal-organic vapor phase epitaxy method to form the epitaxial substrate EP. The first stacked semiconductor layer 15 in the laminate 11 includes first semiconductor layers 15a and second semiconductor layers 15b, which are alternately arranged in the direction of the normal axis Nx so as to form one distributed Bragg reflector. The second stacked semiconductor layer 19 in the laminate 11 includes third semiconductor layers 19a and fourth semiconductor layers 19b, which are alternately arranged in the direction of the normal axis Nx so as to form the other distributed Bragg reflector.

An exemplary of the epitaxial substrate EP.
First stacked semiconductor layer 15: GaAs/AlGaAs superlattice,
First semiconductor layer 15a: GaAs.
Second semiconductor layer 15b: AlGaAs.
Semiconductor region 17.
Quantum well structure MQW: (GaAs/AlGaAs, AlGaInAs/AlGaAs or InGaAs/AlGaAs).
Al-based III-V semiconductor layer 21: AlGaAs.
Second stacked semiconductor layer 19: GaAs/AlGaAs superlattice.
Third semiconductor layer 19a: GaAs.
Fourth semiconductor layer 19b: AlGaAs.
Upper contact layer 25: GaAs.
Buffer layer 23: GaAs.

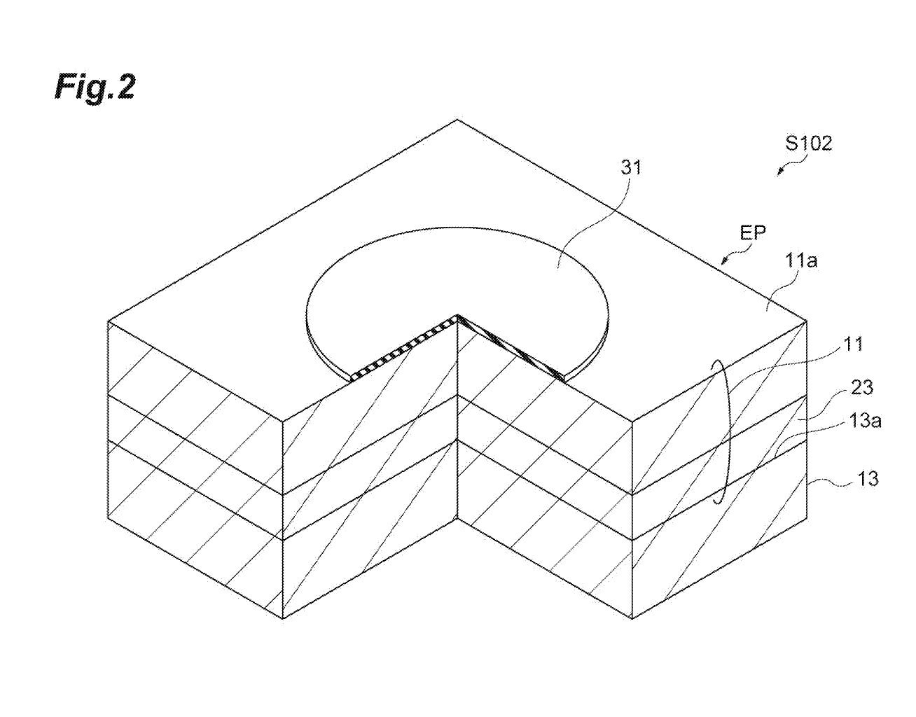

In Step S102, as shown in FIG. 2, a mask 31 is formed on the principal surface of the epitaxial substrate EP. The mask 31 defines the shape of the semiconductor post in which the optical cavity is formed. In the fabrication of the mask 31, an inorganic insulating film (silicon-based inorganic insulating film, such as silicon oxide film, silicon nitride film, and silicon oxynitride film) is formed on the principal surface 11a of the laminate 11 in the epitaxial substrate EP, and photolithography and etching are applied to the inorganic insulating film to form the mask 31, which has a pattern for a semiconductor post.

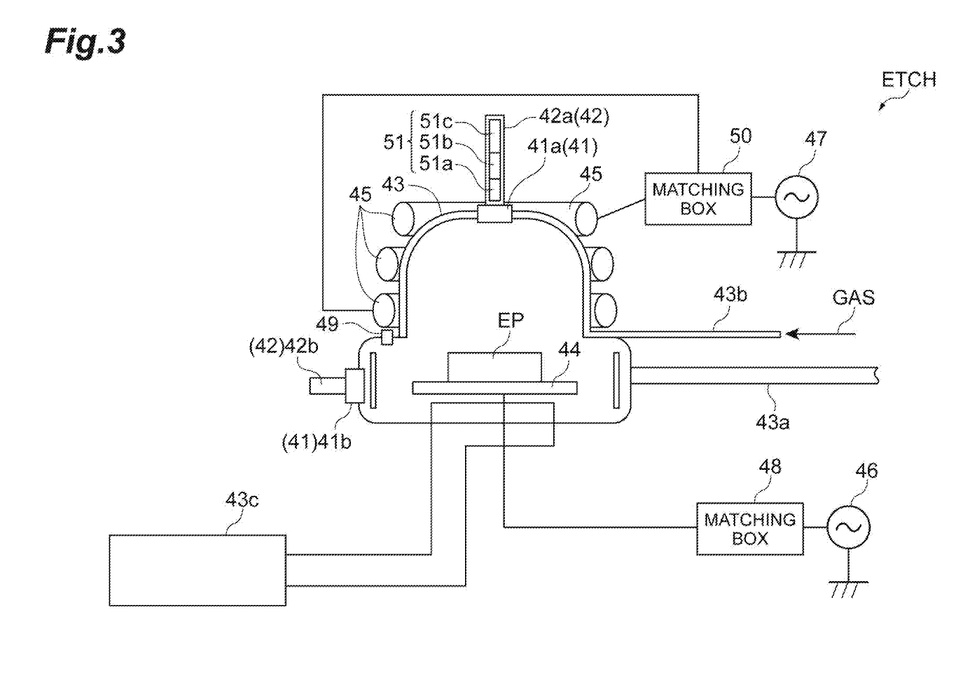

In step S103, an etching apparatus is prepared. FIG. 3 is a schematic view showing an exemplary etching apparatus according to the present embodiment. The etching apparatus ETCH of FIG. 3 includes an inductive-coupled plasma reactive-ion etching (ICP-RIE) device. The etching apparatus ETCH includes a viewport 41 (41a and 41b), an end point detector 42 (42a and 42b), a chamber 43, a lower electrode 44, an inductively coupling coil 45, a first radio frequency power supply 46, a second radio frequency power supply 47, and a pressure gauge 49. The pressure gauge 49 may be, for example, a Balatron vacuum gauge. The chamber 43 is connected to an exhaust pump via an exhaust line 43a and is connected to a gas introduction system 43b for supplying gas GAS, such as process gas and source gas. The chamber 43 includes a dielectric dome, and an inductive-coupling coil 45 is provided outside the dielectric dome of the chamber 43. The lower electrode 44 is disposed in the chamber 43. The epitaxial substrate EP is placed on the lower electrode 54. The first radio frequency power supply 46 is coupled to the lower electrode 44 through a first matching unit 48. The second radio frequency power supply 47 is coupled to the inductively coupling coil 45 through the second matching unit 50. In the present embodiment, the viewport 41a is provided on the ceiling of the dielectric dome to face the lower electrode 44 (or the epitaxial substrate EP on the lower electrode 44). The end point detector 42a receives light (light from the article to be etched) in the dielectric dome through the viewport 41a. If necessary, the lower electrode 44 is coupled to a cooler 43c for adjusting the temperature of the substrate during the etching process.

The end point detector 42 includes an optical device 51 for detecting the end point of the process by receiving light through the viewport 41 of the etching apparatus ETCH. For example, the end point detector 42a has a so-called interference type detector, and the optical device 51 of the end point detector 42a includes a light source 51a and a spectrometer 51b. Such an interference type end point monitor receives the interference light during the etching process to estimate the residual film thickness of the semiconductor laminate for forming the distributed Bragg reflector from the intensity of the light thus received. By monitoring the intensity of the light with the interference-type end point monitor, the end point of the etching is detected.

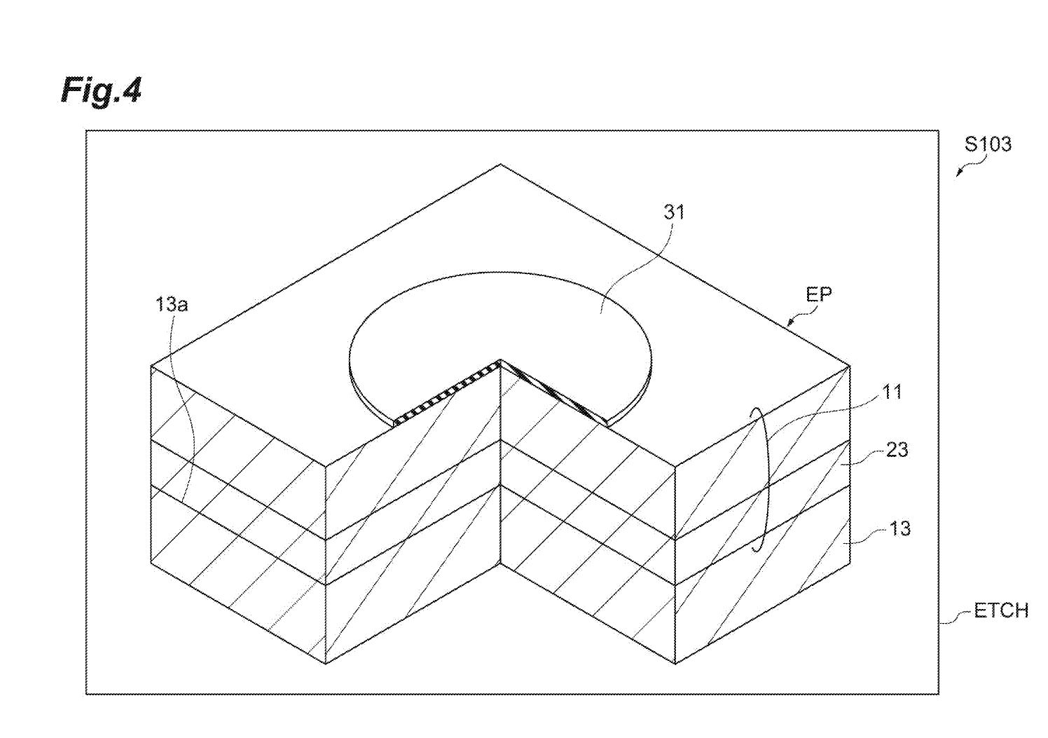

Further, in step S103, after forming the mask 31, the epitaxial substrate EP is placed on the lower electrode 44 of the etching apparatus ETCH as shown in FIG. 4. The chamber 43 of the etching apparatus ETCH is evacuated by using an evacuation pump to obtain a desired vacuum (vacuum pressure) in the chamber 43. After the vacuum evacuation is completed, a gas including the process gas and the etchant is supplied to the chamber 43 of the etching apparatus ETCH. The process gas contains a dilution gas (He and; or Ar), and the dilution gas does not contain any chlorine as a constituent element.

As shown in FIG. 3, an end point detector 42a, such as an interference-type end point monitor is installed on the viewport 41a, which is located on the top of the chamber just above the wafer chuck. Specifically, the interference type end point monitor includes a light source 51a (preferably, a white light source), such as a halogen lamp, a spectrometer 51b which receives reflected light from the article, and an imaging device 51c, such as a CCD camera. The end point detection is performed as follows. First, the CCD camera is aligned to a monitor area (for example, a monitor pattern) which has been already prepared on the wafer. The monitor area has a desired size (for example, the monitor area having an area of 500 micrometers square or more) where the semiconductor is exposed. The light source 51a is directed to the monitor area, which is irradiated with white light emitted from the light source 51a.

The etching with the end point detector 42a thus installed follows the setup of the end point detector 42a. Specifically, gas containing boron chloride and chlorine is supplied to the etching apparatus ETCH to generate the plasma thereof, thereby etching the epitaxial substrate EP. The etchant thus supplied etches both the device area and the monitor area according to the pattern of the mask 31. The monitor area also includes the laminate 11. In the fabrication of the vertical cavity surface emitting laser, the multilayer structure is etched. In the former half of the etching, the second stacked semiconductor layer 19 and the semiconductor region 17 are processed, and in the latter half of the etching, the first stacked semiconductor layer 15 is processed. For example, the first stacked semiconductor layer 15 includes a GaAs/AlGaAs multilayer film, and the substrate 13 includes a GaAs surface. In the present fabricating and monitoring methods, the end point detector 42a receives, through the viewport 41a, both the reflected light components from both the GaAs surface of the substrate and the GaAs/AlGaAs structure of the first stacked semiconductor layer 15 which is currently etched. The end point detector 42a detects the end point by using the interference light of these reflected light components. In response to the end point detection in the end point detector 42a, the plasma etching is stopped.

### EXAMPLE

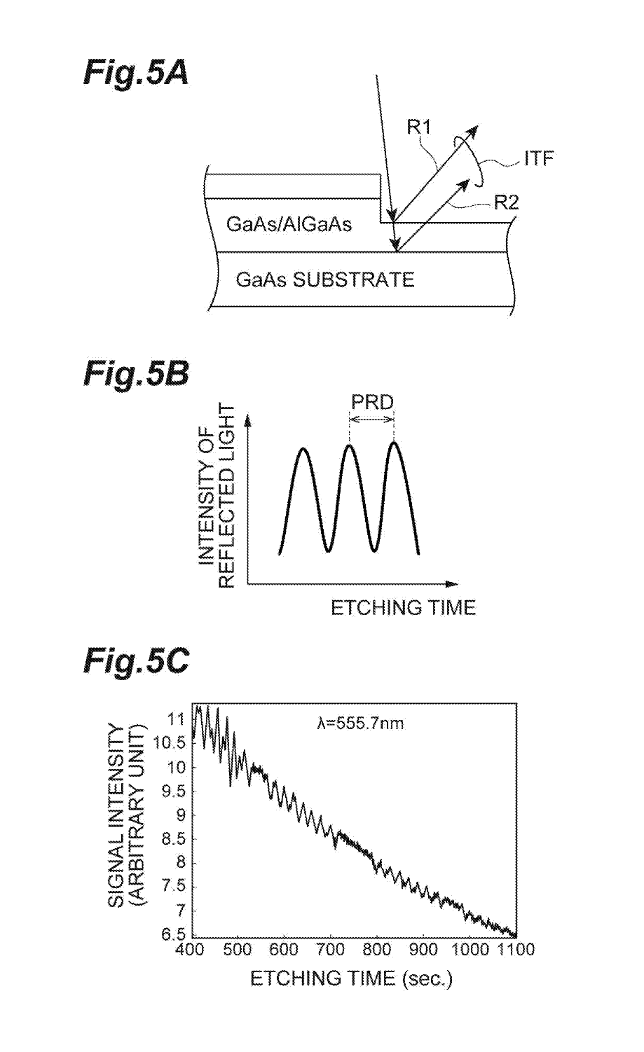

FIGS. 5A, 5B, and 5C are schematic diagrams each showing etching in Examples. In this embodiment, the laminate 11 including a GaAs/AlGaAs multilayer film in the first stacked semiconductor layer 15 disposed on the GaAs substrate are etched. As shown in FIG. 5A, interference light ITF produced by the reflected light components (R1 and R2) from the monitoring area during the etching is observed with a spectrometer. The reflected light component fill indicates reflected light from the etched surface of the laminate 11, which is produced by etching, and the reflected light component R2 indicates reflected light from the principal surface of the GaAs substrate. As shown in FIG. 5B, the intensity of the interference light ITF varies with change in thickness of the remaining part of the laminate 11, which has not been etched yet. The change in thickness may be measured from the optical intensity in real time, and the measured changes are converted into the rate of the change, i.e., the etching rate, to judge the detection of the end point. Alternatively, the number of peaks arranged in the period PRD in the interference waveform in the time period from the start of etching to the end point is associated with the number of semiconductor layers in the first stacked semiconductor layer 15. Counting the number of peaks in the interference waveform permits the judgement that the end point has been detected.

In the etching, BCl₃ reacts with GaAs as follows.
2BCl₃+GaAs→GaCl₃ (gas phase)+AsCl₃ (gas phase)+3B,
BCl₃ reacts with AlGaAs as follows.
3BCl₃+AlGaAs→GaCl₃ (gas phase)+AlCl₃ (gas phase)+AsCl₃ (gas phase)+3B.

Both reactions produce boron products (boron atoms, and boron ions) in the plasma during etching. The gallium chloride, the aluminum chloride and the arsenic chloride thus produced are contained in the gas phase in the chamber, and are exhausted out via the exhaust line. A part of boron thus generated is not exhausted hut remains in the chamber 43.

The end point detection uses monitor light (light from an article in the chamber) which is received through the viewport 41a. Boron compounds, which are produced by decomposition of BCl₃, deposit on the viewport 41a and the inner surface of the chamber 43. Such contamination on the viewport 41a lowers the light intensity from the article that is being etched, leading to increase in noise and reduction in sensitivity.

It is experimentally found that the process pressure during etching is preferably kept within the range of 1.0 Pascal or less. The upper limit of the pressure may prevent the products during etching from accumulating much on the viewport 41a and the inner surface of the chamber 43. A process pressure of less than 1.0 pascal (Pa) increases the mean free path of particles (atoms, molecules, ions) in the chamber, and specifically, allows chlorine ions to have a longer mean free path, so that chloride ions in the plasma may reach the viewport 41a and the inner surface of the chamber 43, thereby contributing to the cleaning of the viewport 41a and the inner surface. In addition, in order to obtain a stable plasma discharge, it is desirable that the process pressure during the etching is 0.5 Pascal or more. The substrate temperature is preferably 25 degrees Celsius or less.

The flow rate of BCl₃ is preferably not more than 10 sccm (6×10⁻⁴ m³/h, which is converted to SI units in standard condition, where a pressure of 1 atm, and a temperature of zero degrees Celsius), and may avoid the excessive formation of boron compounds. In addition, it is preferable to dilute the etchant by nine times or more with a process gas, such as Ar and/or He. Chlorine gas Cl₂ is supplied to the chamber to produce boron chloride (e.g, BCl₃) from the deposited boron, and the boron chloride thus produced is reliably removed from the chamber 43.
2B+3Cl₂→2BCl₃ (gas phase). The ratio of the flow rates of boron trichloride, chlorine and the process gas is, for example, BCl₃: Cl₂; Ar=2:0.5 to 1:7. In the range of the above flow rate ratio of a chlorine (Cl₂) between 0.5 and 1, the chlorine (Cl₂) flow rate ratio of lower than 0.5 may not provide adequate cleaning of the viewport. Increase in the Cl₂ flow rate ratio results in roughening of the etched GaAs surface.

An exemplary flow rate ratio of the etching gas may be, for example: BCl₃/Cl₂/Ar=8 sccm/2 sccm/90 sccm or BCl₃/Cl₂/Ar=5 sccm/5 sccm/90 sccm.

The molar ratio (MC/MB) of the molar amount (MC) of chlorine to the molar amount (MB) of the boron trichloride in the etchant supplied to the chamber during the etching may be 1 or more, and may be 4 or less.

The etching condition of the process pressure according to the present embodiment results in a smaller etching rate than that of a higher process pressure, and may, however, reduce the amount of the deposition on the viewport at the end of etching.

In the etching using etching conditions of a higher process pressure, as shown in FIG. 5C, the amplitude of the interference light varies over the etching period from the start of etching to the end. This change results from depositing material on the viewport. The depositing material on the viewport results in that the signal intensity of the monitoring light is made greatly weak in the latter half of an etching run, as compared with the former half of the etching run. The etching with a lower process pressure in the above pressure range reduces the viewport contamination.

The etching method according to the present embodiment substantially maintain the quality of the mesa etching as it is. Furthermore, the etching method may reduce the contamination depositing on the viewport 41a.

The supply power (ICP power) of the second radio frequency power supply 47 is preferably 50 watts or more. This supply power (ICP power) of 50 watts or more allows the second radio frequency power supply 47 to apply a large power to the inductive-coupling coil 45, so that ions in the plasma can reach the viewport 41a by overcoming the bias power that the first radio frequency power supply 46 applies to the lower electrode 44.

Boron is water soluble, and can be removed by breaking a vacuum of the process chamber to wipe the process chamber with water. Performing such cleaning for each etching run is burdens because of the following reasons. It takes a processing time to wipe the viewport with water, and an additional time to remove water left on the process chamber in water wiping.

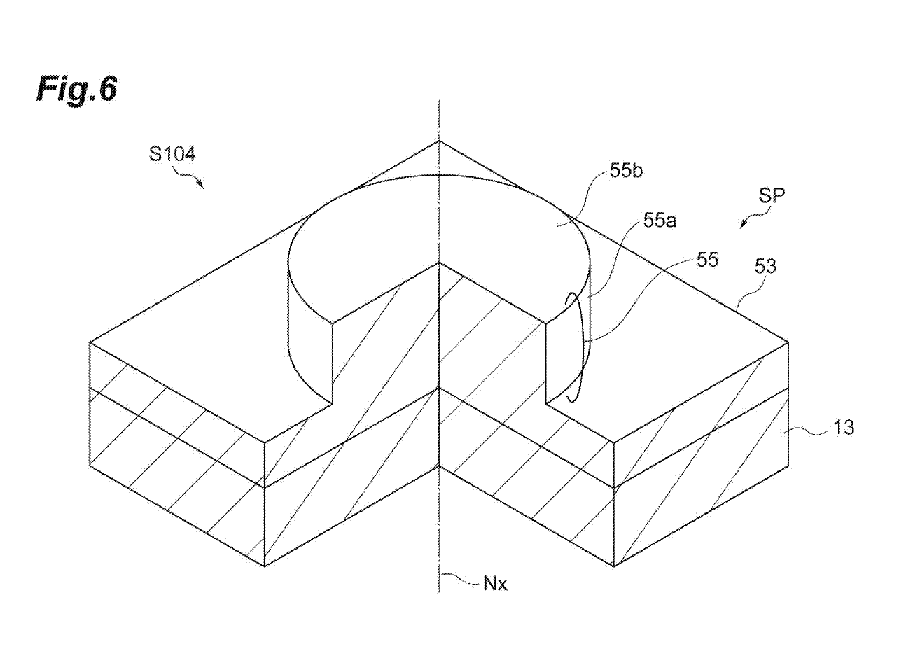

The description of the major steps in the fabricating method follows the above example. The substrate product SP is produced from the epitaxial substrate EP by etching. After removing the substrate product from the etching apparatus ETCH, as shown in FIG. 6, the mask 31 is removed in step S104. The substrate product SP includes the substrate 13 and the semiconductor structure 53, which includes semiconductor posts 55. Each of the semiconductor posts 55 includes a first distributed Bragg reflector, an active layer, and a second distributed Bragg reflector. The semiconductor structure 53 is produced from the laminate structure in the epitaxial substrate EP. The first distributed Bragg reflector, the active layer, and the second distributed Bragg reflector are arranged in the direction of the normal axis Nx. The semiconductor post 55 includes a side face 55a extending in the direction of the normal axis Nx, and a top face 55b extending along a plane intersecting the direction of the normal axis Nx.

In the fabricating method, the etching apparatus ETCH generates plasma of boron chloride and chlorine in the etching apparatus ETCH. Chlorine in the plasma is consumed to produce chlorides of constituent elements of semiconductor, resulting in etching the semiconductor. A part of boron particles in the plasma deposits on the viewport 41a and the inner wall of the chamber 43 of the etching apparatus ETCH. The process pressure of less than one Pascal in the etching may provide the gas phase in the chamber 43 of the etching apparatus ETCH with a mean free path which allows chlorine particles in the plasma to reach the viewport 41a in the chamber 43. Chlorine particles in the plasma may produce chloride from the boron deposition adhering to the viewport 41a, and are consumed to reduce the boron deposition. The above low process pressure allows both etching of the semiconductor and cleaning of the viewport 41a during the etching. The lower process pressure makes the plasma density lower as compared to that of a higher process pressure, and makes the etching time required for completing the formation of the desired semiconductor posts longer. Even after the longer etching time, the deposited material on the viewport 41a is in an acceptable range.

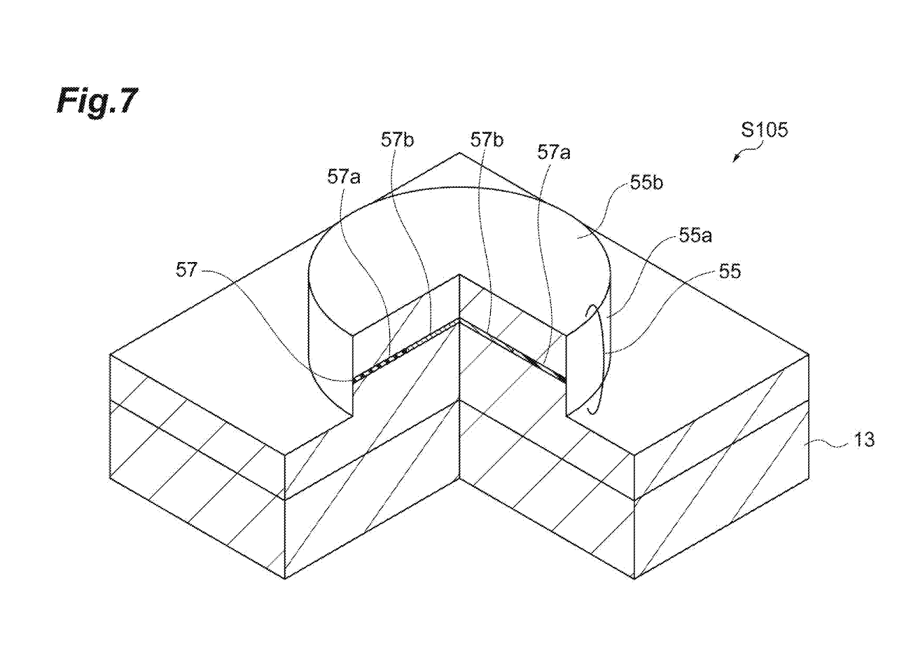

In step S105, as shown in FIG. 7, a current confinement structure is formed in the substrate product SP in an oxidizing atmosphere. In the substrate product SP, the semiconductor post 55 includes an AlGaAs layer with a high Al composition (a layer coming from the semiconductor layer 21 in the laminate 11), which is disposed between the active layer and the second distributed Bragg reflector. In the substrate product SP placed in an oxidizing atmosphere, the AlGaAs layer (the etched III-V semiconductor layer 21) is oxidized from the side 55a of the semiconductor post 55 inward to form a thin aluminum oxide layer 57a, so that an AlGaAs window layer 57b is left in the middle of the post, and the aluminum oxide layer 57a surrounds the AlGaAs window layer 57b. The oxidizing atmosphere includes, for example, high temperature steam.

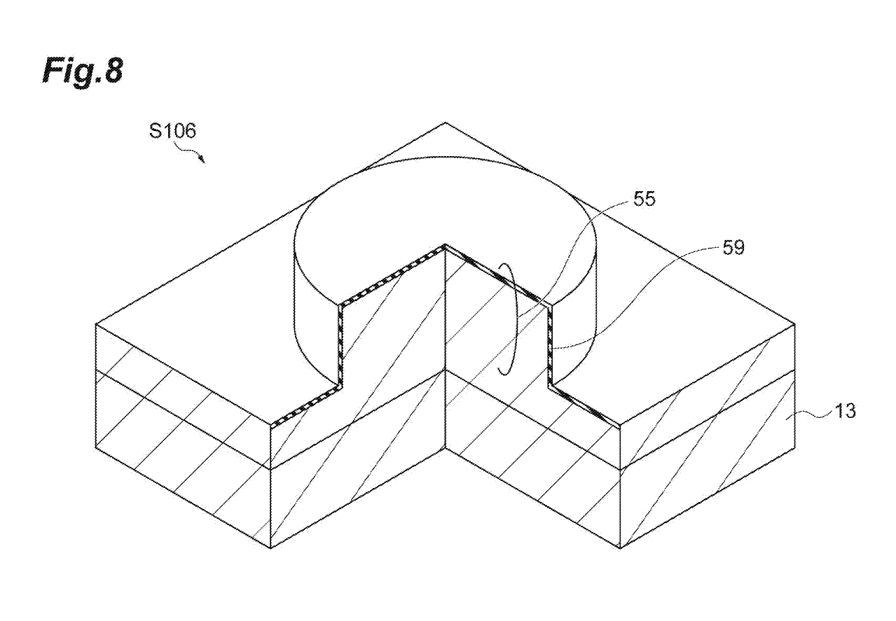

In step S106, after forming the current confinement structure, the passivation film 59 is formed on the entire surface as shown in FIG. 8. The passivation film 59 may be formed by, for example, a plasma CVD method, and includes a silicon-based inorganic insulating film, such as SiN film, SiON film or SiO₂ film. The passivation film 59 may have a film thickness adjusted such that the passivation film 59 acts as a high reflection film around the wavelength of light emitted from the surface emitting laser.

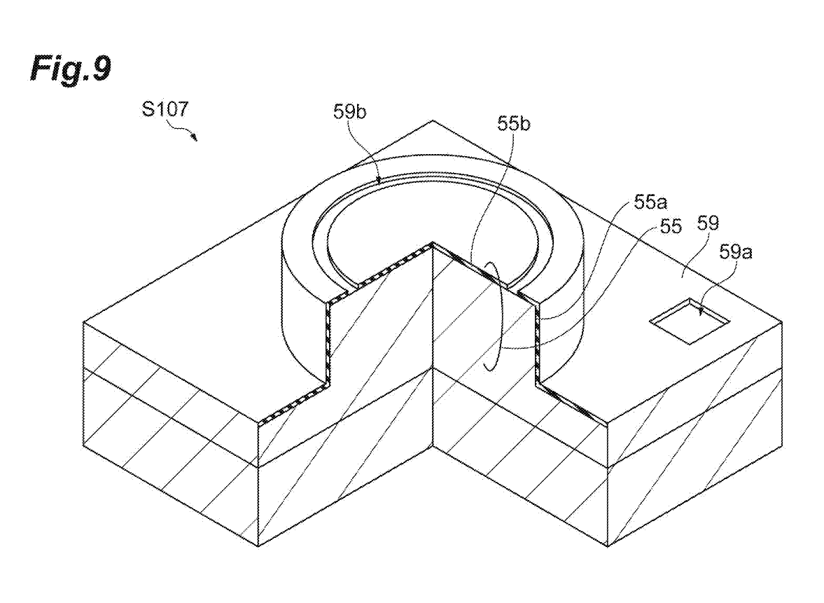

In step S107, after forming the passivation film 59, as shown in FIG. 9, openings are formed for electrode formation in the passivation film 59 by using the etching and photolithography methods. In the present embodiment, the passivation film 59 includes a first opening 59a provided on the buffer layer, and a second opening 59b provided on the upper face 55b of the semiconductor post 55.

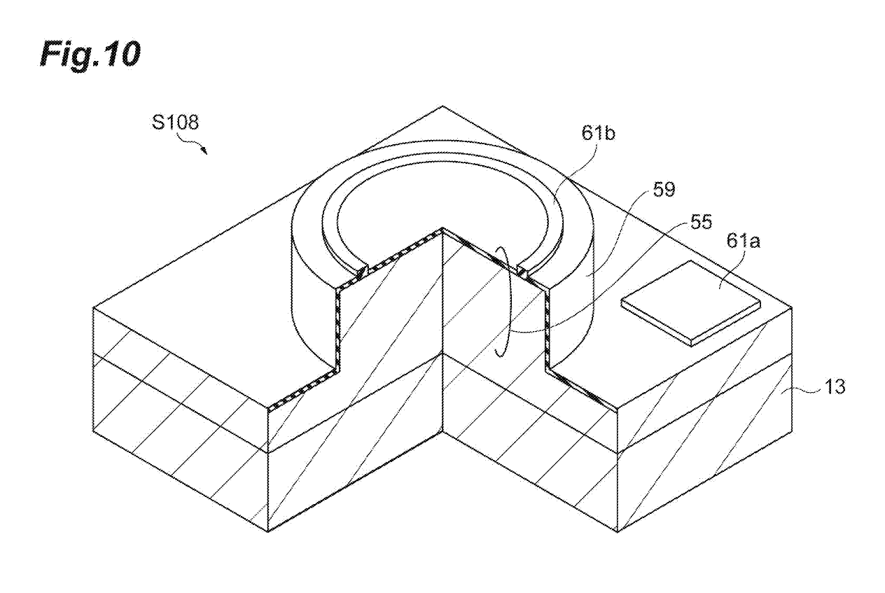

In step S108, after forming the passivation film 59, as shown in FIG. 10, the first electrode 61a and the second electrode 61b are formed in the first opening 59a and the second opening 59b, respectively. Each of the first electrode 61a and the second electrode 61b may have a Ti/Pt/Au laminate structure.

The above steps fabricate the surface emitting laser, which has a shape of a semiconductor chip as shown in FIG. 10.

The method for fabricating a surface emitting laser includes etching used to form semiconductor posts each of which has a height of several micrometers (for example, four micrometers or more), in the present embodiment, five micrometers. Such an etching requires, for example, 15-minute process time. Such a long etching time causes accumulation of dirt (contamination) depositing on the viewport during the etching, and the contamination interferes with acquisition of the endpoint detection signal near the end point of the etching. In order to overcome the problem, a high process pressure of about five Pa higher than one Pa is used to increase the ion density in the plasma, thereby increasing the etching rate. Increase in etching rate allows a desired etching to end in several minutes, for example, about five minutes. Before contamination of the viewport is made noticeable, the etching for forming the semiconductor post ends. Dirt is, however, observed on the viewport after the etching is completed. The dirt comes from boron deposition caused by the free radical of boron produced by decomposition of boron trichloride, which is used as an enchant.

In the embodiment, boron deposits are converted into boron chloride during the etching to remove the boron deposits. Producing boron chloride from the deposited material is promoted by lowering the process pressure rather than increasing the process pressure that makes the plasma density high. It is experimentally found that lowering a process pressure makes the mean free path of particles in the chamber long. Such etching conditions are applied to the fabrication of semiconductor optical devices which requires dry etching with boron chloride, thereby providing the above technical contribution.

Having described and illustrated the principle of the invention in a preferred embodiment thereof, it is appreciated by those having skill in the art that the invention can be modified in arrangement and detail without departing from such principles. We therefore claim all modifications and variations coming within the spirit and scope of the following claims.

What is claimed is:

1. A method for fabricating a surface emitting laser comprising the steps of:
preparing an epitaxial substrate including a substrate and a laminate disposed on the substrate, the laminate including a first Bragg reflector, an active layer, and a second Bragg reflector;
forming a mask for defining a semiconductor post on the epitaxial substrate;
after forming the mask, placing the epitaxial substrate in a chamber of an etching apparatus with an end point detector including an optical device;
carrying out plasma etching of the epitaxial substrate with the mask by supplying a gas including boron chloride and chlorine in the chamber of the etching apparatus; and
stopping the plasma etching in response to an end point detection from the end point detector of the etching apparatus,
wherein the optical device of the end point detector detects an end point of a process through a viewport of the etching apparatus, and
the plasma etching is carried out in a process pressure of one Pascal or less.

2. The method according to claim 1,
wherein the end point detector has an optical interference type detector, and
the optical device includes an optical source and a spectrometer.

3. The method according to claim 1,
wherein the first Bragg reflector in the laminate includes a GaAs/AlGaAs superlattice, and
the substrate has a GaAs surface.

4. The method according to claim 1,
wherein the etching apparatus includes a stage having a lower electrode, an inductive-coupling coil disposed outside the chamber thereof, a first radio frequency power supply coupled to the lower electrode, and a second radio frequency power supply coupled to the inductive-coupling coil,
the epitaxial substrate is placed on the stage during the plasma etching, and
the second radio frequency power supply has a capability of supplying a power of 50 watts or more.
